(19) United States
(12) Patent Application Publication
(10) Pub. No.: US 2005/0083641 A1
(43) Pub. Date: Apr. 21, 2005

(54) Central processing unit

(76) Inventor: Shu-Ju Lin, Taipei (TW)

Correspondence Address: BIRCH STEWART KOLASCH & BIRCH, PO BOX 747, FALLS CHURCH, VA, 22040-0747, US

(21) Appl. No.: 10/688,874

(22) Filed: Oct. 21, 2003

(51) Int. Cl. H05K 5/00

(52) U.S. Cl. 361/679

(57) ABSTRACT

A central processing unit (CPU) that has a die on one side and a radiator mounting onto the side of the CPU where the die is located includes a protection wall surrounding the die. The protection wall prevents the radiator from directly hitting the CPU during mounting thereby protects the CPU from being damaged and facilitates installation of the radiator.

### FIELD OF THE INVENTION

The invention relates to a central processing unit (CPU) that has a protection feature to prevent the CPU from being damaged when a radiator is mounted onto the side where the CPU die is located.

### BACKGROUND OF THE INVENTION

Electronic devices have become necessary household goods in people's life nowadays. Electronic devices generally have heat-generating elements, which generate heat energy when in use. Hence the electronic devices mostly have a heat dissipation structure to disperse the heat energy and maintain the electronic devices at a suitable temperature to function normally. In the electronic devices, CPU is the element that generates a great amount of heat energy. The mostly commonly adopted heat dissipation approach for CPU is to mount a radiator onto the die of CPU (as shown in FIG. 1). Such an approach provides single thermal resistance value (only the die surface is in contact with the radiator). In addition, when coupled with phase changing heat transfer elements such as heat tubes, it also has a lower boiling superheat and can result in a lower thermal resistance. However, such a structure is prone to damage the CPU when mounting the radiator.

To remedy this problem, many protection elements for CPU have been developed. FIG. 2A and FIG. 2B show one of the examples. It has a cap covering the die. The radiator is mounted onto the cap. But such a design has to take the matching between the cap and the die into account. The inner surface of the cap must be in contact with the outer surface of the die and the outer surface of the cap must be in contact with the surface of the radiator to disperse heat energy. Moreover, two thermal resistance values are involved (one thermal resistance value for the contact between the cap and the die, and another thermal resistance value for the contact between the cap and the radiator). Hence heat dissipation suffers.

FIG. 3 illustrates another CPU protection design that includes a metal plate with a carved out opening corresponding to the electronic elements of the CPU. The metal plate has anchor edges on the periphery to connect to the CPU edges. Such a design requires fabricating many metal plates of different specifications to mate different dimensions of the CPU. Moreover, the metal plates increase the material and fabrication costs of the products.

FIG. 4 depicts yet another design of a CPU protection element. It has a bracing bracket located between the radiator and the CPU. The bracing bracket has a mounting opening and a bracing elastic sheet on the surrounding edges of the opening to support the radiator. However when in use for separating the radiator from the CPU, the radiator tends to be bounced away. Moreover, the bracing elastic sheet is subjected to elastic fatigue after being used for a period of time. In addition, in the process of mounting or releasing the radiator, the distance between the elements still is a problem to be considered, to avoid damaging the CPU. It also incurs many specifications and higher costs. All this becomes a serious drawback.

### SUMMARY OF THE INVENTION

Therefore the primary object of the invention is to provide a CPU with a protection feature to avoid damaging the CPU when mounting a radiator onto one side of the CPU where the die is located and facilitate fabrication.

The CPU according to the invention includes a die on one side. When a radiator is mounted onto the side of the CPU where the die is located, the CPU is protected from being damaged. The CPU has a protection wall surrounding the die. The protection wall has a height the same as that of the die.

The protection wall may be consecutive to house the die, or be inconsecutive to include a plurality of protection members. The protection members are spaced from one another and surround the die. Thus when the radiator is mounted onto the side of the CPU where the die is located, the protection wall can prevent the radiator from directly hitting the CPU. Moreover, the invention has only one thermal resistance value (the contact surface between the die and the radiator). It can speed up heat dissipation of the CPU. In addition, when phase changing thermal transfer elements such as heat tubes are used, a lower boiling superheat may be obtained.

The foregoing, as well as additional objects, features and advantages of the invention will be more readily apparent from the following detailed description, which proceeds with reference to the accompanying drawings.

### BRIEF DESCRIPTION OF THE DRAWINGS

FIG. 1 is a schematic view of a conventional CPU with the radiator directly mounting thereon.

FIG. 2A and FIG. 2B are a schematic view of a conventional CPU with a protection wall.

FIG. 3 is a schematic view of another conventional CPU with a protection wall.

FIG. 4 is a schematic view of yet another conventional CPU with a protection wall.

FIG. 5 is a perspective view of the invention.

FIG. 6 is a sectional view of the invention with the radiator mounting onto the CPU.

FIG. 7 is a perspective view of another embodiment of the invention.

FIG. 8 is a sectional view of another embodiment of the invention with the radiator mounting onto the CPU.

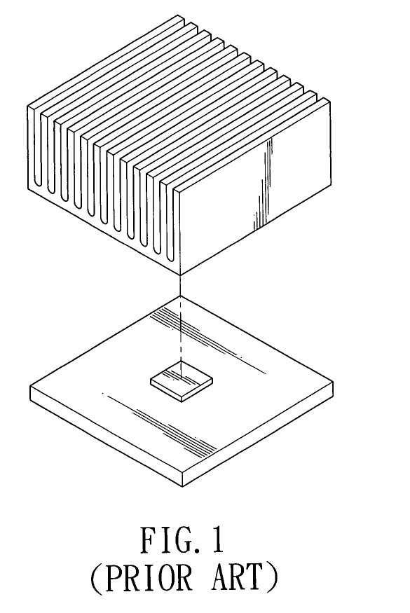

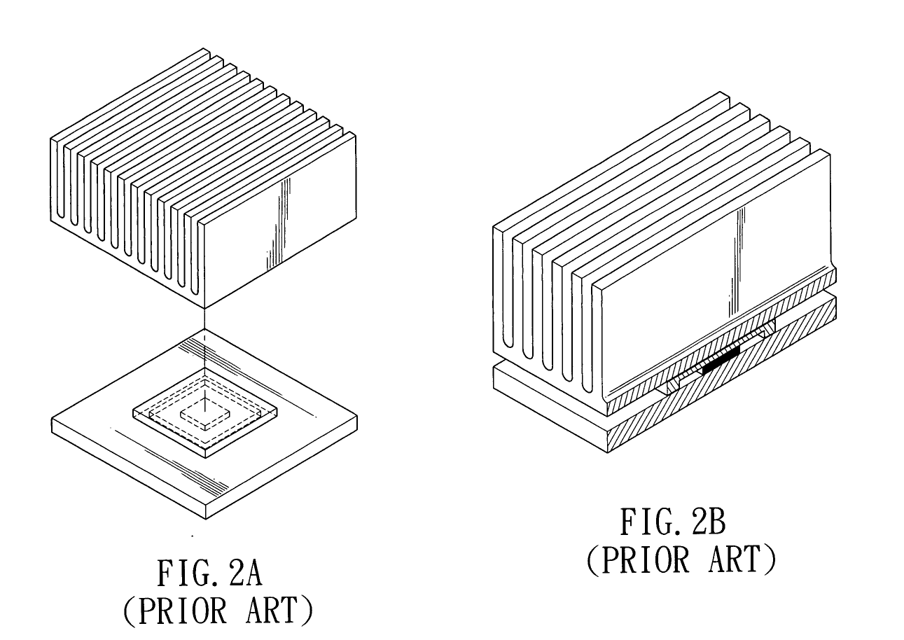

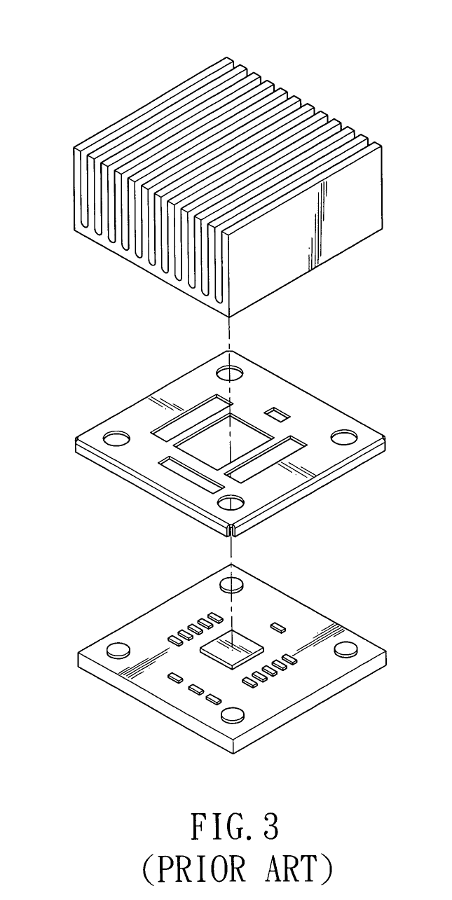

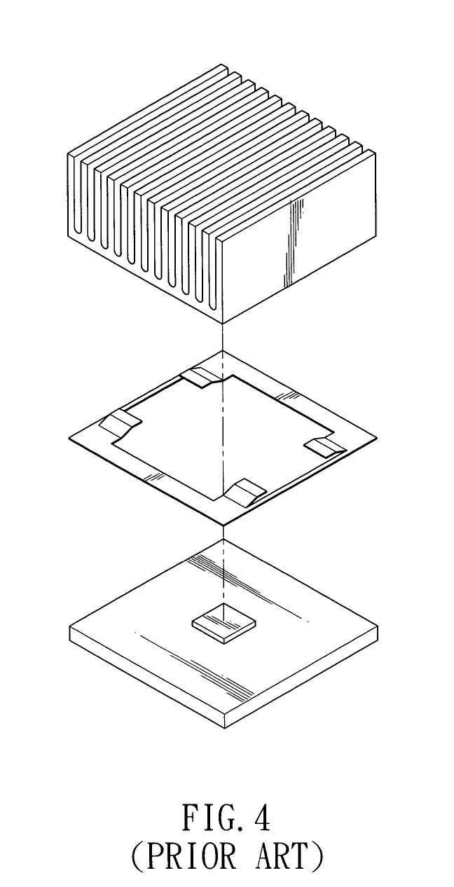

### DESCRIPTION OF THE PREFERRED EMBODIMENTS

Referring to FIG. 5, the CPU 2 according to the invention has a die 21 located on one side and a radiator 1 mounting onto the side of the CPU 2, where the die 21 is located without damaging the CPU 2.

The invention mainly includes a protection wall 3 surrounding the die 21. The protection wall 3 has a height the same as that of the die 21. The protection wall 3 is formed in a consecutive manner for housing the die 21.

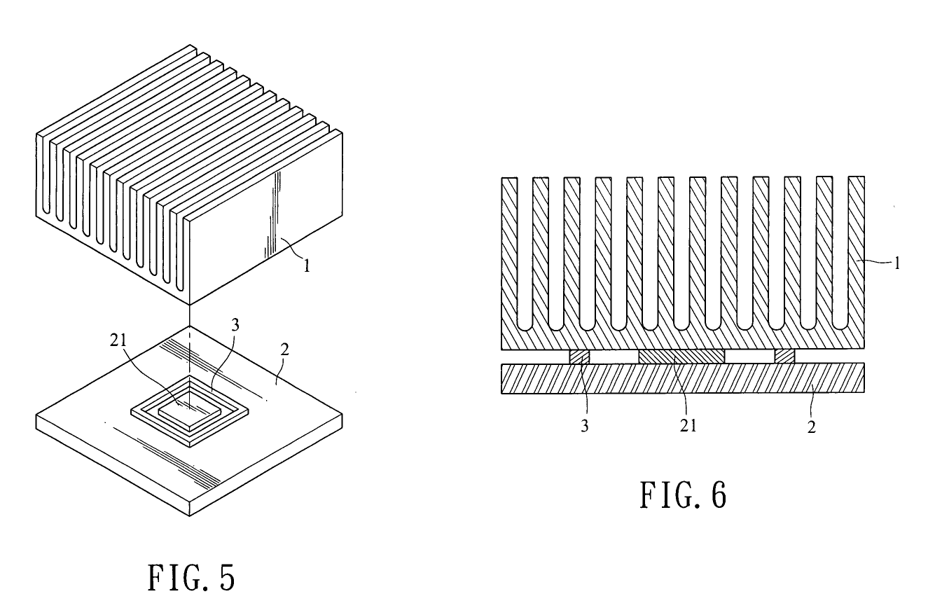

Referring to FIG. 6, when the radiator 1 is mounted onto the side of the CPU 2 where the die 21 is located, the protection wall 3 prevents the radiator 1 from directly hitting the CPU 2. And a single thermal resistance value is formed (between the die 21 and the radiator 1). Therefore heat energy of the CPU 2 can be dispersed rapidly. Moreover, when phase-changing heat transfer elements such as heat tubes are being used, a lower boiling superheat may be achieved.

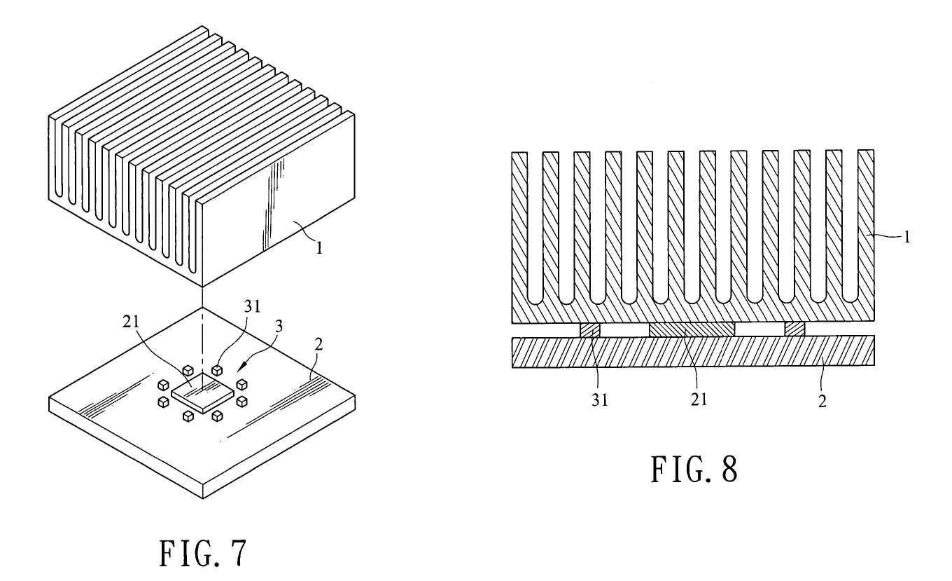

Refer to FIG. 7 for another embodiment of the invention. The CPU 2 according to the invention has a die 21 located on one side and a radiator 1 mounting onto the side of the CPU 2 where the die 21 is located without damaging the CPU 2.

The invention mainly includes a protection wall 3 surrounding the die 21. The protection wall 3 has a height the same as that of the die 21. The protection wall 3 is formed in an inconsecutive manner and includes a plurality of protection members 31, which are spaced from one another for housing the die 21.

Referring to FIG. 8, when the radiator 1 is mounted onto the side of the CPU 2 where the die 21 is located, the protection wall 3 prevents the radiator 1 from directly hitting the CPU 2. And a single thermal resistance value is formed (between the die 21 and the radiator 1). Therefore heat energy of the CPU 2 can be dispersed rapidly. Moreover, when phase-changing heat transfer elements such as heat tubes are being used, a lower boiling superheat may be achieved.

While the preferred embodiments of the invention have been set forth for the purpose of disclosure, modifications of the disclosed embodiments of the invention as well as other embodiments thereof may occur to those skilled in the art. Accordingly, the appended claims are intended to cover all embodiments which do not depart from the spirit and scope of the invention.

1. A central processing unit that has a die on one side used for mounting a radiator onto the side of the central processing unit where the die is located without damaging the central processing unit, comprising a protection wall surrounding the die.

2. The central processing unit of claim 1, wherein the protection wall has a height same as that of the die.

3. The central processing unit of claim 1, wherein the protection wall is formed in a consecutive manner for housing the die.

4. The central processing unit of claim 1, wherein the protection wall is formed in an inconsecutive manner and includes a plurality of protection members spaced from one another for housing the die.
